(19) United States
(12) Patent Application Publication
(10) Pub. No.: US 2023/0093515 A1
(43) Pub. Date: Mar. 23, 2023

(54) SYNCHRONOUS BUCK CONVERTER USING A SINGLE GATE DRIVE CONTROL

(71) Applicant: National Yang Ming Chiao Tung University, Hsinchu (TW)

(72) Inventors: Wei-Hua Chieng, Hsinchu (TW); Edward Yi Chang, Hsinchu (TW); Stone Cheng, Hsinchu (TW); Shyr-Long Jeng, Hsinchu (TW); Li-Chuan Tang, Hsinchu (TW); Chih-Chiang Wu, Hsinchu (TW); Ching-Yao Liu, Hsinchu (TW); Kuo-Bin Wang, Hsinchu (TW)

(21) Appl. No.: 17/539,243

(22) Filed: Dec. 1, 2021

(30) Foreign Application Priority Data
Sep. 17, 2021 (TW) 110134909

(51) Int. Cl. H02M 3/158; H01L 29/20

(52) U.S. Cl. CPC H02M 3/1582; H01L 29/2003

(57) ABSTRACT

A synchronous buck converter using a single gate drive control is provided and includes a drive circuit, a p-type gallium nitride (p-GaN) transistor switch module and an inductor. A gallium nitride power transistor is used as an upper side transistor switch, and a PMOS power transistor is used as a lower side transistor switch in the p-GaN transistor switch module. A gate of the upper side transistor switch and a gate of the lower side transistor switch are coupled to each other and receive a switch signal provided by the drive circuit at the same time. By controlling the on and off of the upper side transistor switch and the lower side transistor switch, the problem of simultaneous activation of the upper and lower side transistor switches can be avoided.

### BACKGROUND

### 1. Technical Field

The present disclosure relates to the technique of step-down conversion, and more particularly, to a synchronous buck converter using a single gate drive control.

### 2. Description of Related Art

As the performance of computer, communication and consumer electronic products (3C products) such as smartphones increases, the power consumption also increases. Therefore, 3C products have higher and higher requirements for devices that provide power. In response to the aforementioned requirements, the conventional technology usually uses a buck converter to convert the input power into the corresponding power output suitable for the 3C products so as to provide the power of the 3C products.

Nowadays, the circuit topology of direct current to direct current (DC-DC) buck converters for providing power has been widely used. The conventional buck converters are usually composed by metal-oxide-semiconductor field-effect transistors (MOSFETs). However, in order to prevent two switches from turning on at the same time, the conventional buck converter must precisely control the gate driver to control the switch timing between the MOSFETs (i.e., dead time control), so that the buck converter would not be overheated or damaged due to poor power conversion rate when providing power output. In addition, if the switching of the on and off of the MOSFETs of the buck converter can be operated at a high frequency, the voltage or current after the step-down would be more stable. Further, under the consideration of miniaturization, reducing the volume of the inductors, capacitors and other components in the buck converter and therefore reducing the size of the circuit board are also the goal pursued by one of ordinary skill in the art.

It can be seen from the above that how to provide a better gate driver design to improve the operating efficiency of the buck converter and provide efficient energy to meet the needs of modern people for the use of power is important for the development of the buck converter. Therefore, how to overcome the various problems of the aforementioned prior art is becoming an urgent issue to be solved at present.

### SUMMARY

In view of the aforementioned problems of the prior art, the present disclosure provides a synchronous buck converter using a single gate drive control, which comprises: a drive circuit configured for providing a switch signal; a p-type gallium nitride transistor switch module coupled to the drive circuit and including: an upper side transistor switch with a source coupled to a power input terminal; and a lower side transistor switch with a source and a drain coupled to a drain of the upper side transistor switch and a ground, respectively, wherein gates of the upper side transistor switch and the lower side transistor switch are coupled to each other and receive the switch signal at the same time to control on or off of the upper side transistor switch and the lower side transistor switch; and an inductor with one terminal coupled with the drain of the upper side transistor switch and the source of the lower side transistor switch to step down and convert an input power of the power input terminal to an output power, wherein the output power is outputted via a power output terminal located at the other terminal of the inductor.

In one embodiment, the lower side transistor switch is a p channel power transistor, and the upper side transistor switch is a depletion-mode gallium nitride power transistor.

In one embodiment, the p-type gallium nitride transistor switch module further includes a compensation unit having a diode and a compensation capacitor, wherein the gate of the lower side transistor switch is coupled with the gate of the upper side transistor switch via the compensation unit, wherein an anode of the diode and an anode of the compensation capacitor are coupled with the gate of the upper side transistor switch, and wherein a cathode of the diode and a cathode of the compensation capacitor are coupled with the gate of the lower side transistor switch.

In one embodiment, the switch signal includes a positive voltage signal and a negative voltage signal. Further, when the switch signal is the positive voltage signal, the upper side transistor switch is turned on and the lower side transistor switch is turned off, and when the switch signal is the negative voltage signal, the upper side transistor switch is turned off and the lower side transistor switch is turned on.

In one embodiment, the drive circuit includes a gate drive unit and a biased unit coupled to the gate drive unit, wherein when the drive circuit receives an input gate power and an input power signal, the drive circuit is controlled by an operation of the input power signal, and the input gate power is biased via the biased unit to form the switch signal.

In one embodiment, the input power signal has a switching frequency of 500 KHz to 2 MHz.

In one embodiment, the drive circuit further includes a charging gate resistor, a discharging gate resistor and a coupling capacitor, wherein the gate drive unit is coupled with an anode of the coupling capacitor via the charging gate resistor and the discharging gate resistor and coupled with the biased unit via a cathode of the coupling capacitor.

In one embodiment, the biased unit includes a diode, a capacitor and a Zener diode, wherein an anode of the diode and an anode of the capacitor are coupled with the cathode of the coupling capacitor, wherein a cathode of the diode and a cathode of the capacitor are coupled with a cathode of the Zener diode, and wherein an anode of the Zener diode is coupled to the ground.

In one embodiment, the present disclosure further comprises a filter unit having a filter capacitor with an anode coupled to the inductor and a cathode coupled to the ground.

In summary, a synchronous buck converter using a single gate drive control according to the present disclosure uses a gallium nitride power transistor as an upper side transistor switch and a PMOS power transistor as a lower side transistor switch. A gate of the upper side transistor switch and a gate of the lower side transistor switch are coupled to each other and receive a switch signal provided by a drive circuit at the same time. By respectively controlling the on and off of the upper side transistor switch and the lower side transistor switch, the objective of not turning on the upper side transistor switch and the lower side transistor switch at the same time would be achieved, thereby extending the service life of the buck converter. Moreover, the synchronous buck converter using the single gate drive control according to the present disclosure accepts a higher switching frequency, provides a stable output power and reduces the size of the components and circuits, thereby achieving the purpose of reducing the product size.

### BRIEF DESCRIPTION OF THE DRAWINGS

FIG. 1 is a circuit diagram of a synchronous buck converter using a single gate drive control according to the present disclosure.

FIG. 2 is a circuit diagram of a compensation unit of a p-type gallium nitride transistor switch module in a synchronous buck converter using a single gate drive control according to the present disclosure.

FIG. 3 is a detailed circuit diagram of a synchronous buck converter using a single gate drive control according to the present disclosure.

FIG. 4 is a detailed circuit diagram of a drive circuit of a synchronous buck converter using a single gate drive control according to the present disclosure.

FIG. 5A and FIG. 5B show test results of a synchronous buck converter using a single gate drive control according to the present disclosure.

FIG. 6A and FIG. 6B show output power and overall efficiency of a synchronous buck converter using a single gate drive control according to the present disclosure at 500 KHz and 1 MHz, respectively.

### DETAILED DESCRIPTION OF THE EMBODIMENTS

Implementations of the present disclosure are described below by specific embodiments. Those skilled in the art can easily understand other advantages and technical effects of the present disclosure based on the content disclosed in this specification, and also implement or apply other equivalent implementations.

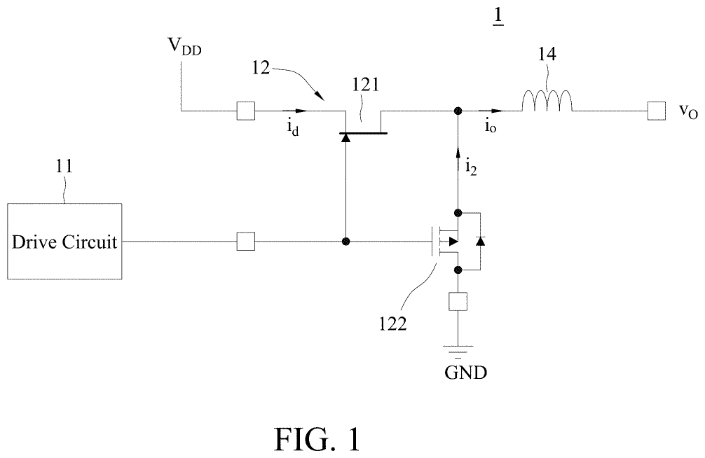

FIG. 1 is a circuit diagram of a synchronous buck converter using a single gate drive control according to the present disclosure. As shown in FIG. 1, a synchronous buck converter 1 using a single gate drive control includes a drive circuit 11, a p-type gallium nitride (p-GaN) transistor switch module 12 and an inductor 14 coupled to each other. The present disclosure controls the switching of an internal switch of the p-GaN transistor switch module 12 via the drive circuit 11, so that the p-GaN transistor switch module 12 can provide an output power by passing an input power through the inductor 14 (where the inductor 14 converts and steps down the input power). The detailed description related to the synchronous buck converter 1 using a single gate drive control according to the present disclosure is as follows.

The drive circuit 11 is configured to provide a switch signal. The synchronous buck converter 1 using a single gate drive control controls the switching of the internal switch of the p-GaN transistor switch module 12 via the switch signal. In an embodiment, the switch signal is a positive voltage signal or a negative voltage signal.

The p-GaN transistor switch module 12 is coupled to the drive circuit 11 and includes an upper side transistor switch 121 and a lower side transistor switch 122. The upper side transistor switch 121 can be a depletion-mode gallium nitride power transistor (GaN high-electron-mobility transistor or GaN HEMT). The p-GaN transistor switch module 12 is coupled to a power input terminal (i.e., input location of an input voltage V_{DD}) via a source of the upper side transistor switch 121 so as to receive the input power of the power input terminal (e.g., input voltage V_{DD}). Moreover, the lower side transistor switch 122 can be a p channel power transistor (P-channel metal-oxide-semiconductor or PMOS). A source of the lower side transistor switch 122 is coupled to a drain of the upper side transistor switch 121, and a drain of the lower side transistor switch 122 is coupled to a ground GND. The p-GaN transistor switch module 12 according to the present disclosure is mainly composed of the depletion-mode gallium nitride power transistor stacked in series with the PMOS power transistor, and gates of the depletion-mode gallium nitride power transistor and the PMOS power transistor are electrically connected to each other. The upper side transistor switch 121 and the lower side transistor switch 122 can receive the switch signal of the drive circuit 11 at the same time since the gate of the upper side transistor switch 121 is coupled with the gate of the lower side transistor switch 122, where the switch signal is used to turn on or turn off the corresponding upper side transistor switch 121 or lower side transistor switch 122. As such, the p-GaN transistor switch module 12 can form an output power (e.g., output voltage V_{O}) by passing the input power of the power input terminal (e.g., input voltage V_{DD}) through the inductor 14 (where the inductor 14 steps down and converts the input power) and output the output power that has been stepped down and converted via the power output terminal of the other terminal of the inductor 14 (i.e., output voltage V_{O}).

One terminal of the inductor 14 is coupled with the drain of the upper side transistor switch and the source of the lower side transistor switch so as to step down and convert the input power of the power input terminal to the output power, where the output power is outputted from the other terminal of the inductor 14, which is the power output terminal thereof.

The switch signal of the drive circuit 11 can be a voltage signal (e.g., square wave including positive voltage signal or negative voltage signal) so as to directly drive the on (conduction) or off of the upper side transistor switch 121 and the lower side transistor switch 122 of the p-GaN transistor switch module 12. That is, when the switch signal is a positive voltage signal, the depletion-mode gallium nitride power transistor (i.e., the upper side transistor switch) is conducted or turned on and the PMOS power transistor (i.e., the lower side transistor switch) is turned off. When the depletion-mode gallium nitride power transistor is conducted or turned on, an input current i_{d} is generated, which flows to the power output terminal and is connected to the inductor 14, so that an output current iₒ of the inductor 14 changes in a gradually increasing manner. On the contrary, when the switch signal is a negative voltage signal, the depletion-mode gallium nitride power transistor is turned off and the PMOS power transistor is conducted or turned on. When the PMOS power transistor is conducted or turned on, a conduction current i₂ is generated, which flows to the power output terminal and is connected to the inductor 14, so that the output current iₒ of the inductor 14 changes in a gradually decreasing manner, thereby forming the corresponding output voltage V_{O} and the output current iₒ. That is, the output voltage V_{O} and the output current iₒ are formed by the inductor 14, and the related signal waveforms will be described in detail in the following paragraphs.

In the synchronous buck converter 1 using a single gate drive control according to the present disclosure, since the gate of the depletion-mode gallium nitride power transistor is coupled with the gate of the PMOS power transistor and the depletion-mode gallium nitride power transistor and the PMOS power transistor are configured to receive the switch signal of the drive circuit 11 at the same time, only a single power transistor can be conducted when the switch signal is a positive voltage signal or a negative voltage signal. That is, when the switch signal of the drive circuit 11 is switched between positive and negative voltages, dead time control is not required, which can not only prevent the depletion-mode gallium nitride power transistor and the PMOS power transistor from the problem of shooting through at the same time, but also prevent the problem of damage to the synchronous buck converter 1 using a single gate drive control due to poor conversion rate, thereby effectively extending the service life of the synchronous buck converter 1 using a single gate drive control. In addition, the synchronous buck converter 1 using a single gate drive control according to the present disclosure is configured to use a gallium nitride power transistor, which can increase the switching frequency of the switch signal to 500 KHz-2 MHz so as to provide a more stable output power (e.g., output voltage or output current), thereby achieving the effects of reducing the volume of internal components and reducing the size of the circuit board.

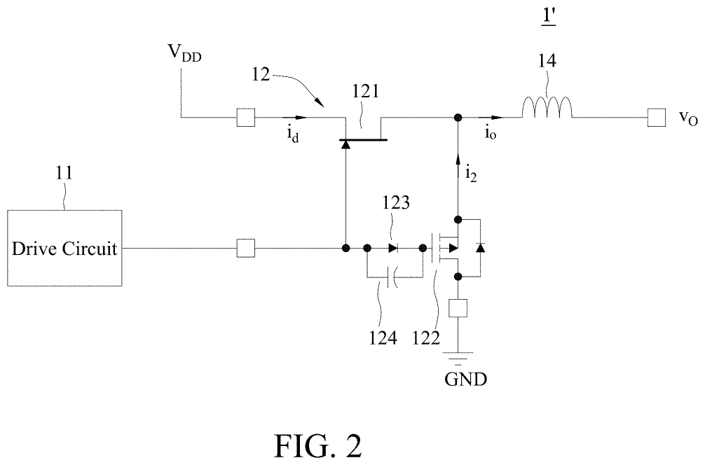

FIG. 2 is a circuit diagram of a compensation unit of the p-GaN transistor switch module 12 in a synchronous buck converter using a single gate drive control according to the present disclosure. As shown in FIG. 2, in an embodiment, a synchronous buck converter 1′ using a single gate drive control includes the drive circuit 11, the p-GaN transistor switch module 12 and the inductor 14. The p-GaN transistor switch module 12 further includes a compensation unit having a diode 123 and a compensation capacitor 124. The gate of the lower side transistor switch 122 is coupled with the gate of the upper side transistor switch 121 via the compensation unit. An anode of the diode 123 and an anode of the compensation capacitor 124 are coupled with the gate of the upper side transistor switch 121, and a cathode of the diode 123 and a cathode of the compensation capacitor 124 are coupled with the gate of the lower side transistor switch 122. Accordingly, when the switch signal is a positive voltage signal, the diode 123 is conducted, and at this time the PMOS power transistor is free from being conducted. On the other hand, when the switch signal is a negative voltage signal, the diode 123 is free from being conducted, and at this time the negative voltage signal is divided by the compensation capacitor 124 and a parasitic capacitor between the gate and the source of the PMOS power transistor so as to conduct the PMOS power transistor. In other words, through the compensation capacitor 124 designed in the gate of the PMOS according to the present disclosure, a gate input impedance of the depletion-mode gallium nitride power transistor is matched with a gate input impedance of the PMOS power transistor. Therefore, a situation where the depletion-mode gallium nitride power transistor and the PMOS power transistor are conducting at the same time can be avoided.

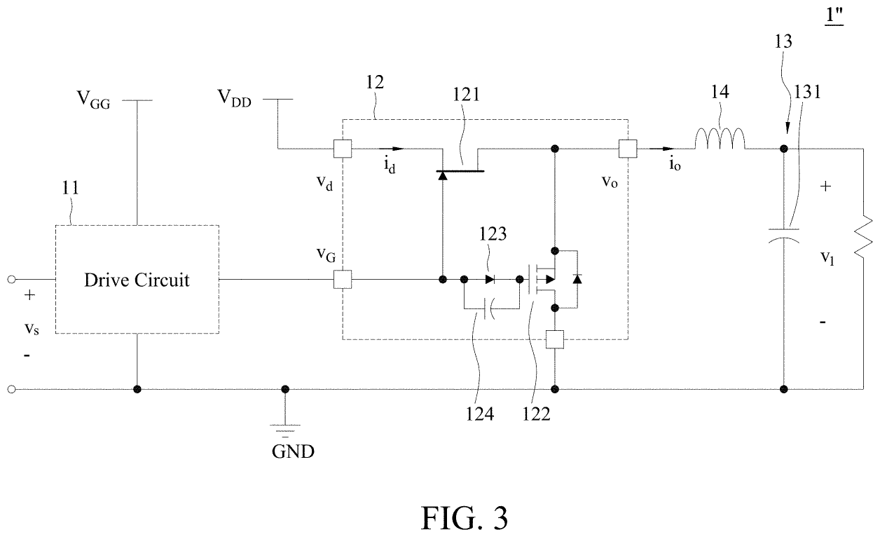

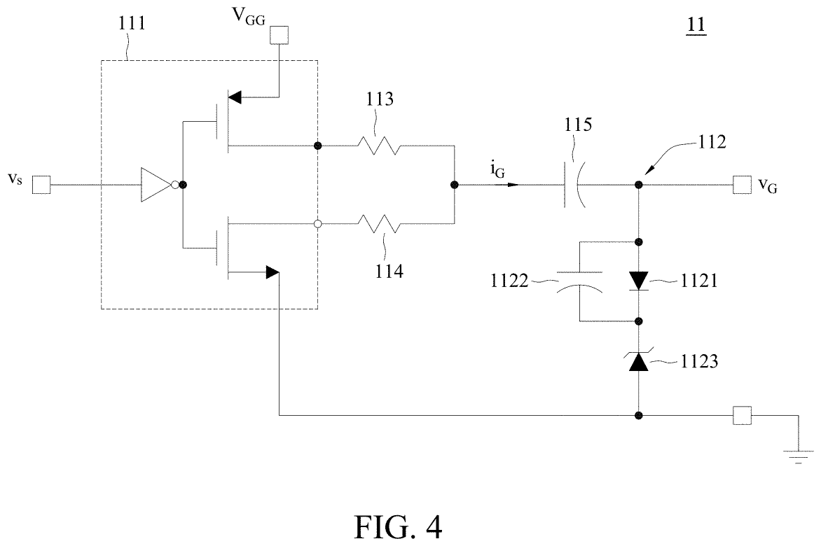

FIG. 3 is a detailed circuit diagram of a synchronous buck converter using a single gate drive control according to the present disclosure. FIG. 4 is a detailed circuit diagram of a drive circuit of the synchronous buck converter using a single gate drive control according to the present disclosure. Please refer to FIG. 3 and FIG. 4 together. As shown in FIG. 3 and FIG. 4, the drive circuit 11 can be a biased type charge pump drive circuit and includes a gate drive unit 111 and a biased unit 112 coupled to the gate drive unit 111. The drive circuit 11 further includes a charging gate resistor 113, a discharging gate resistor 114, and a coupling capacitor 115. The gate drive unit 111 is coupled with an anode of the coupling capacitor 115 via the charging gate resistor 113 and the discharging gate resistor 114 and is coupled with the biased unit 112 via a cathode of the coupling capacitor 115. Moreover, the biased unit 112 includes a diode 1121, a capacitor 1122, and a Zener diode 1123. An anode of the diode 1121 and an anode of the capacitor 1122 are coupled with a cathode of the coupling capacitor 115, and a cathode of the diode 1121 and a cathode of the capacitor 1122 are coupled with a cathode of the Zener diode 1123. That is, the diode 1121 and the Zener diode 1123 are in opposing series. The anode of the Zener diode 1123 is coupled to the ground GND, and the Zener diode 1123 can increase a voltage value of an output voltage V_{G} of the drive circuit 11. Accordingly, when the drive circuit 11 receives an input gate power and an input power signal, the drive circuit 11 is controlled by the operation of the input power signal, and the input gate power is biased via the biased unit 112 to form a switch signal. For example, when the input gate power is an input gate voltage V_{GG} and a breakdown voltage of the Zener diode 1123 is V_{Z}, the biased unit 112 is biased (that is, after the input gate power is biased via the Zener diode 1123), so that the switch signal is V_{Z} to V_{Z}−V_{GG}. For instance, when the input gate power is a positive voltage signal of 10 volts and the breakdown voltage of the Zener diode 1123 is 5 volts, the biased unit 112 is biased (that is, after the input power signal is biased via the Zener diode 1123), the switch signal of 5 volts to negative 5 volts can be formed.

In an embodiment, the switching frequency of the input power signal is 500 KHz to 2 MHz, thereby forming the switch signal having the switching frequency of 500 KHz to 2 MHz.

In addition, a synchronous buck converter 1″ using a single gate drive control according to an embodiment further includes a filter unit 13. The filter unit 13 has a filter capacitor 131 with an anode coupled to the inductor 14 and a cathode coupled to the ground GND, so that the input voltage V_{DD} is converted to an output voltage (e.g., power supply voltage V₁) under the cooperation of the p-GaN transistor switch module 12 and the coupled inductor 14 and filter capacitor 131.

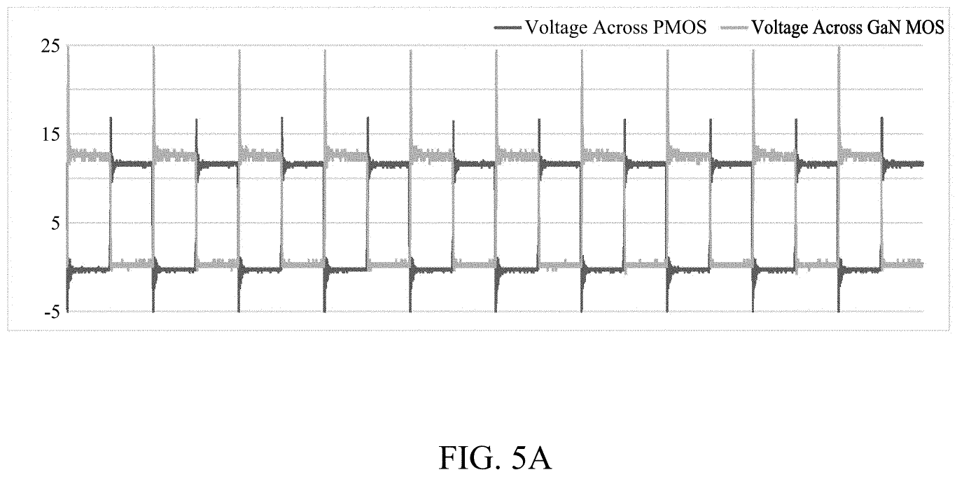

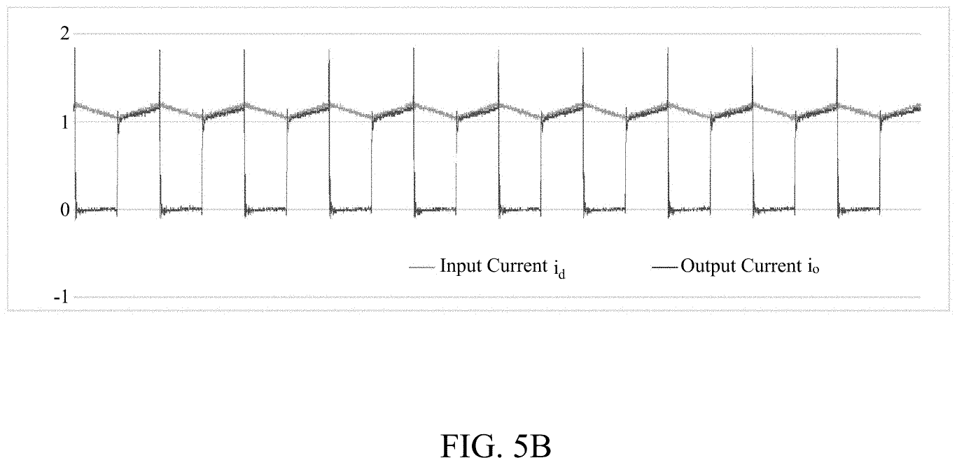

FIG. 5A and FIG. 5B show test results of a synchronous buck converter using a single gate drive control according to the present disclosure. FIG. 5A and FIG. 5B show the experimental results of a 12 V voltage stepping down to 6.5 V under the conditions of switching frequency at 500 kHz and duty cycle at 50%. FIG. 5A shows the voltage across the source and the drain of each power transistor when the depletion-mode gallium nitride power transistor (GaN HEMT) and the PMOS power transistor are turned on and off. FIG. 5B shows the relationship between the input current i_{d} and the output current iₒ. As shown from FIG. 5A and FIG. 5B, in the synchronous buck converter using a single gate drive control according to the present disclosure, when the depletion-mode gallium nitride power transistor is switched on, the current flowing through the depletion-mode gallium nitride power transistor is the input current, and the input current flows to the output inductor (i.e., inductor 14 of FIG. 3) in a gradually increasing manner. When the PMOS power transistor is switched on, the output inductor causes the current to flow back in a gradually decreasing manner to charge the filter capacitor (i.e., filter capacitor 131 of FIG. 3). Since the present disclosure operates at a higher switching frequency, as such, the output power is actually a flat voltage and current. Moreover, as shown in FIG. 5A and FIG. 5B, each power transistor of the synchronous buck converter using a single gate drive control according to the present disclosure can indeed be switched without being turned on at the same time.

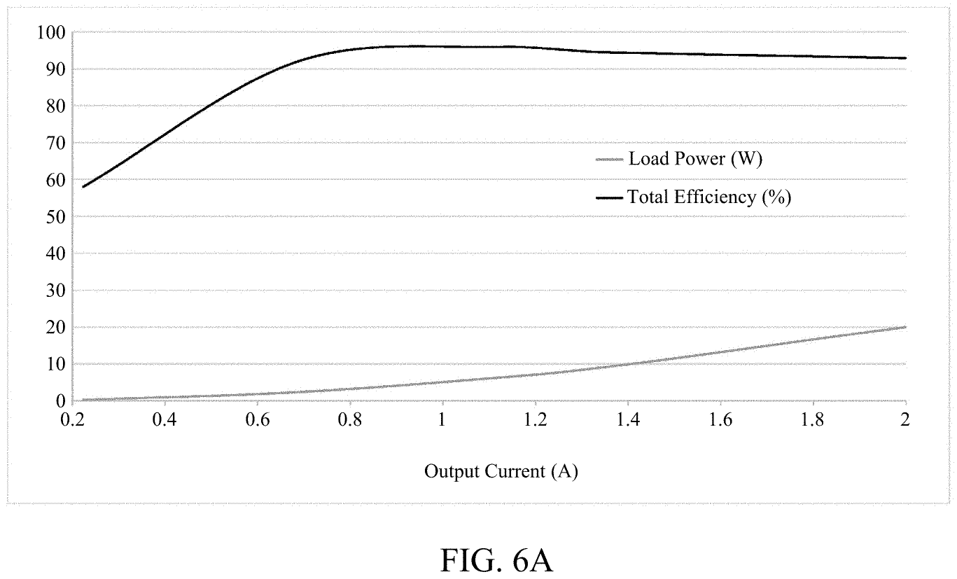

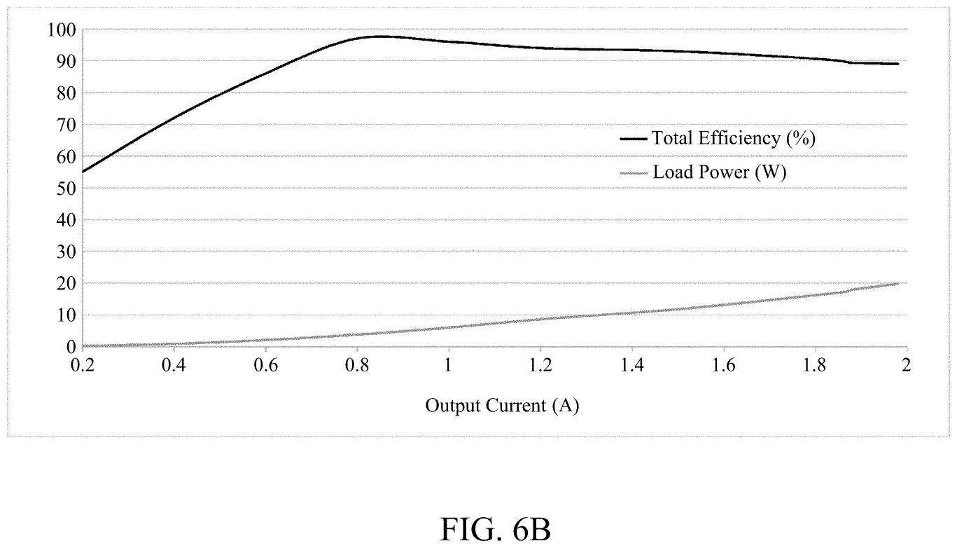

Furthermore, FIG. 6A and FIG. 6B show output power and overall efficiency of a synchronous buck converter using a single gate drive control according to the present disclosure at 500 KHz and 1 MHz, respectively. As shown in FIG. 6A, the total efficiency of the present disclosure exceeds 92% when the switching frequency is 500 kHz and the load power is an output of 20 W; and as shown in FIG. 6B, the total efficiency of the present disclosure is 89% when the switching frequency is 1 MHz and the load power is an output of 20 W. Accordingly, the present disclosure would indeed maintain good power conversion at higher frequencies.

In summary, the present disclosure provides a synchronous buck converter using a single gate drive control, through the design of a p-GaN transistor switch module using a depletion-mode gallium nitride power transistor and a PMOS power transistor, gates of the depletion-mode gallium nitride power transistor and the PMOS power transistor are coupled and connected to a drive circuit. When the drive circuit provides a switch signal, the gates of the depletion-mode gallium nitride power transistor and the PMOS power transistor can receive the switch signal provided by the drive circuit at the same time, so that the switching of the switch can be directly controlled without the need to additionally install a processor as in the prior art. Therefore, the switching between the power transistors can be precisely controlled without dead time control, thereby preventing the problem of power transistors conducting at the same time. As such, the present disclosure would achieve the effect of extending the service life of the synchronous buck converter. Moreover, the synchronous buck converter using a single gate drive control according to the present disclosure would accept a higher switching frequency and provide a stable output power, thereby achieving the purpose of reducing the size of the product via reducing the size of the component and circuit.

The above-described descriptions of the detailed embodiments are to illustrate the preferred implementation according to the present disclosure, and it is not to limit the scope of the present disclosure. Accordingly, all modifications and variations completed by those with ordinary skill in the art should fall within the scope of present disclosure defined by the appended claims.

What is claimed is:

1. A synchronous buck converter using a single gate drive control, comprising:
a drive circuit configured for providing a switch signal;
a p-type gallium nitride transistor switch module coupled to the drive circuit and comprising:
an upper side transistor switch with a source coupled to a power input terminal; and
a lower side transistor switch with a source and a drain coupled to a drain of the upper side transistor switch and a ground, respectively, wherein gates of the upper side transistor switch and the lower side transistor switch are coupled to each other and receive the switch signal at a same time to control on or off of the upper side transistor switch and the lower side transistor switch; and
an inductor with one terminal coupled with the drain of the upper side transistor switch and the source of the lower side transistor switch to step down and convert an input power of the power input terminal to an output power, wherein the output power is outputted via a power output terminal located at the other terminal of the inductor.

2. The synchronous buck converter of claim 1, wherein the lower side transistor switch is a p channel power transistor, and the upper side transistor switch is a depletion-mode gallium nitride power transistor.

3. The synchronous buck converter of claim 1, wherein the p-type gallium nitride transistor switch module further includes a compensation unit having a diode and a compensation capacitor, wherein the gate of the lower side transistor switch is coupled with the gate of the upper side transistor switch via the compensation unit, wherein an anode of the diode and an anode of the compensation capacitor are coupled with the gate of the upper side transistor switch, and wherein a cathode of the diode and a cathode of the compensation capacitor are coupled with the gate of the lower side transistor switch.

4. The synchronous buck converter of claim 1, wherein the switch signal includes a positive voltage signal and a negative voltage signal.

5. The synchronous buck converter of claim 4, wherein when the switch signal is the positive voltage signal, the upper side transistor switch is turned on and the lower side transistor switch is turned off, and wherein when the switch signal is the negative voltage signal, the upper side transistor switch is turned off and the lower side transistor switch is turned on.

6. The synchronous buck converter of claim 1, wherein the drive circuit includes a gate drive unit and a biased unit coupled to the gate drive unit, and wherein when the drive circuit receives an input gate power and an input power signal, the drive circuit is controlled by an operation of the input power signal, and the input gate power is biased via the biased unit to form the switch signal.

7. The synchronous buck converter of claim 6, wherein the input power signal has a switching frequency of 500 KHz to 2 MHz.

8. The synchronous buck converter of claim 6, wherein the drive circuit further includes a charging gate resistor, a discharging gate resistor and a coupling capacitor, and wherein the gate drive unit is coupled with an anode of the coupling capacitor via the charging gate resistor and the discharging gate resistor and coupled with the biased unit via a cathode of the coupling capacitor.

9. The synchronous buck converter of claim 8, wherein the biased unit includes a diode, a capacitor and a Zener diode, wherein an anode of the diode and an anode of the capacitor are coupled with the cathode of the coupling capacitor, wherein a cathode of the diode and a cathode of the capacitor are coupled with a cathode of the Zener diode, and wherein an anode of the Zener diode is coupled to the ground.

10. The synchronous buck converter of claim 1, further comprising a filter unit having a filter capacitor with an anode coupled to the inductor and a cathode coupled to the ground.
